(19) United States
(12) Patent Application Publication
(10) Pub. No.: US 2024/0239563 A1
(43) Pub. Date: Jul. 18, 2024

(54) TOP COVER SEALING STRUCTURE FOR LIQUID COOLING BOX BODY OF DATA ROOM

(71) Applicant: Hebei Qinhuai Data Co., Limited., Zhangjiakou City (CN)

(72) Inventors: Binghua ZHANG, Zhangjiakou City (CN); Mingjiang LI, Zhangjiakou City (CN)

(21) Appl. No.: 18/402,307

(22) Filed: Jan. 2, 2024

(30) Foreign Application Priority Data
Jan. 12, 2023 (CN) 202310041577.6

(51) Int. Cl. B65D 45/02; H05K 7/20

(52) U.S. Cl. CPC B65D 45/02; H05K 7/208

(57) ABSTRACT

The present disclosure discloses a top cover sealing structure for a liquid cooling box body of a data room, at least including a box body and a top cover. One side of the top cover is hinged with the box body and can cover an opening of the box body. The box body is provided with a pressure rod, which can press the top cover towards the box body. The pressure rod is provided with a spring, and a free end of the pressure rod is detachably provided with a pressure block.

### CROSS REFERENCE TO RELATED APPLICATION

This application claims priority to Chinese Patent Application No. 202310041577.6, titled “TOP COVER SEALING STRUCTURE FOR LIQUID COOLING BOX BODY OF DATA ROOM” and filed to the China National Intellectual Property Administration on Jan. 12, 2023, the entire contents of which are incorporated herein by reference.

### TECHNICAL FIELD

The present disclosure relates to the field of a liquid cooling box body for heat transfer, and more particularly, to a top cover sealing structure for the liquid cooling box body of a data room.

### BACKGROUND

Modern data centers undertake a large amount of data computation and storage, which requires increasingly higher system performance stability. To provide higher energy efficiency to meet needs for business development, heat dissipation of servers and even computer rooms has become crucial. As is well known, if the heat dissipation is poor, high temperature not only reduces operating stability of chips, but also generates excessive thermal stress due to temperature difference between internal environment and external environment of modules, which adversely affects electrical performance, operating frequency, mechanical strength, and reliability of the chips.

Compared to traditional air conditioning systems, the most popular liquid cooling technology in the current industry is more advantageous in solving the problem of “heat dissipation of data centers with high heat density”. This liquid cooling technology is quicker in temperature reduction and is lower in energy consumption, and is most friendly to environment.

Liquid cooling refers to a cooling method that uses a liquid with higher specific heat capacity as a working fluid for heat transfer to meet needs for heat dissipation of IT equipment such as servers. Common liquid cooling technologies include immersion cooling, spray cooling, and cold plate cooling.

To ensure normal operation of a liquid cooling box body, it is required to ensure airtightness of the box body. This is because leakage of the liquid cooling box body may cause damage to key components such as chips, and also may cause serious damage to the liquids inside the box body, thus having severe consequences.

Most of the existing liquid cooling box bodies are additionally provided with reinforced structures on their top covers, which increases weight of the top covers and thus is disadvantageous to maintenance by operation and maintenance staff when it is unable to achieve expected sealing effects.

### SUMMARY

Objectives of the present disclosure are to provide a top cover sealing structure for a liquid cooling box body of a data room, which can ensure airtightness of the liquid cooling box body while meeting lightweight of the top cover.

To achieve the above objectives, in one aspect the present disclosure provides a top cover sealing structure for a liquid cooling box body of a data room, which at least includes a box body and a top cover. One side of the top cover is hinged with the box body and can cover an opening of the box body. The box body is provided with a pressure rod, which can press the top cover towards the box body. The pressure rod is provided with a spring, and a free end of the pressure rod is detachably provided with a pressure block.

As a further improvement of the technical solutions, one end of the pressure rod is hinged with a side wall of the box body, other end of the pressure rod is forked to form two bending structures, and the pressure block is sleeved at an end of the bending structure. A length of the pressure rod is less than or equal to a distance between an upper surface of the top cover and a hinge point of the pressure rod. When the pressure rod rotates, the spring can cause a corner of the bending structure to be clamped by an edge of the top cover. The pressure block is positioned inside the bending structure, and a downward pressure applied to the top cover can be provided.

As a further improvement of the technical solutions, a bottom surface of the top cover is provided with a sealing block, and the sealing block matches a shape of an opening of the box body. When the top cover is closed, the sealing block can come into contact with the opening.

As a further improvement of the technical solutions, a size of the sealing block is smaller than the opening. When the top cover is closed, the sealing block is positioned inside the opening, and an outer wall of the sealing block comes into contact with an inner wall of the opening.

As a further improvement of the technical solutions, the bottom surface of the top cover is provided with a sealing groove matching a shape of the sealing block, where the sealing block is arranged inside the sealing groove, a size of the sealing block is smaller than that of the sealing groove, and an end of the sealing block extends towards a direction of the box body. The sealing block is made of a material that can generate elastic deformation. When the top cover is closed, a bottom surface of the sealing block comes into contact with an upper surface of the box body, and the box body squeezes the sealing block such that the sealing block fills the sealing groove.

As a further improvement of the technical solutions, the bottom surface of the top cover is provided with a sealing structure. The sealing structure includes a plurality of sealing installation plates and sealing bodies, where the plurality of sealing installation plates are arranged along an edge of the top cover, and each of the plurality of sealing installation plates is provided with at least one of the sealing bodies. The box body is provided, along an edge of the opening, with sealing holes equal to the sealing bodies in number and corresponding to the sealing bodies in position from up to down. When the top cover is closed, the sealing bodies can be inserted into the corresponding sealing holes.

As a further improvement of the technical solutions, the sealing bodies are made of metal material, and buffer rubber is provided at bottoms of the sealing bodies and inside the sealing holes.

As a further improvement of the technical solutions, the sealing bodies are made of elastic material. When the sealing bodies come into contact with the sealing holes, the sealing holes squeeze the sealing bodies, such that the sealing bodies fill the sealing holes.

As a further improvement of the technical solutions, a visible window is arranged on the top cover.

As can be seen from the present disclosure, a pressure rod is hinged on the box body, and a bending structure is located by means of a spring provided on the pressure rod itself, such that position regulation can be carried out according to a thickness of the top cover to ensure that the pressure block can compress the top cover tightly, thereby reducing a distance between the top cover and the box body, and improving the airtightness of the liquid cooling box body.

Furthermore, the pressure block is detachable, and an appropriate weight of the pressure block may be selected according to needs, which further increases the pressure of the pressure rod against the top cover.

### BRIEF DESCRIPTION OF THE DRAWINGS

To describe the technical solutions of the embodiments of the present disclosure more clearly, the accompanying drawings required for describing the embodiments will be briefly introduced below. Apparently, the accompanying drawings in the following description are merely some embodiments of the present disclosure. To those of ordinary skills in the art, other accompanying drawings may also be derived from these accompanying drawings without creative efforts.

FIG. 1 is a front view of a liquid cooling box body according to an embodiment of the present disclosure;

FIG. 2 is a schematic diagram of a usage status of the liquid cooling box body according to an embodiment of the present disclosure;

FIG. 3 is a schematic diagram of a usage status of the liquid cooling box body according to another embodiment of the present disclosure;

FIG. 4 is a schematic diagram of a usage status of a top cover according to an embodiment of the present disclosure;

FIG. 5 is a schematic diagram of a usage status of the top cover according to another embodiment of the present disclosure;

FIG. 6 is a schematic structural diagram of the top cover according to an embodiment of the present disclosure; and

FIG. 7 is a schematic structural diagram of a box body according to an embodiment of the present disclosure.

Reference numerals in the accompanying drawings:
box body 1; top cover 2; visible window 21; sealing groove 22; sealing structure 3; sealing installation plate 31; sealing body 32; pressure rod 4; bending structure 41; spring 42; sealing block 5; and sealing hole 6.

### DETAILED DESCRIPTION

Detailed description of embodiments of the present disclosure will further be made below with reference to the accompanying drawings to make the above objectives, technical solutions and advantages of the present disclosure more apparent. Terms such as “upper” , “above” , “lower” , “below”, “first end”, “second end”, “one end”, “other end” and the like as used herein, which denote spatial relative positions, describe the relationship of one unit or feature relative to another unit or feature in the accompanying drawings for the purpose of illustration. The terms of the spatial relative positions may be intended to include different orientations of the device in use or operation other than the orientations shown in the accompanying drawings. For example, the units that are described as “below” or “under” other units or features will be “above” other units or features if the device in the accompanying drawings is turned upside down. Thus, the exemplary term “below” can encompass both the orientations of above and below. The device may be otherwise oriented (rotated by 90 degrees or facing other directions) and the space-related descriptors used herein are interpreted accordingly.

In addition, the terms “installed”, “arranged”, “provided”, “connected”, “slidably connected”, “fixed” and “sleeved” should be understood in a broad sense. For example, the “connection” maybe a fixed connection, a detachable connection or integrated connection, a mechanical connection or an electrical connection, a direct connection or indirect connection by means of an intermediary, or an internal connection between two apparatuses, components or constituent parts. For those of ordinary skill in the art, concrete meanings of the above terms in the present disclosure may be understood based on concrete circumstances.

Modern data centers undertake a large amount of data computation and storage, which requires increasingly higher system performance stability. To provide higher energy efficiency to meet needs for business development, heat dissipation of servers and even computer rooms has become crucial. As is well known, if the heat dissipation is poor, high temperature not only reduces operating stability of chips, but also generates excessive thermal stress due to temperature difference between internal environment and external environment of modules, which adversely affects electrical performance, operating frequency, mechanical strength, and reliability of the chips.

Compared to traditional air conditioning systems, the most popular liquid cooling technology in the current industry is more advantageous in solving the problem of “heat dissipation of data centers with high heat density”. This liquid cooling technology is quicker in temperature reduction and is lower in energy consumption, and is most friendly to environment. Liquid cooling refers to a cooling method that uses a liquid with higher specific heat capacity as a working fluid for heat transfer to meet needs for heat dissipation of IT equipment such as servers. Common liquid cooling technologies include immersion cooling, spray cooling, and cold plate cooling.

To ensure normal operation of a liquid cooling box body, it is required to ensure airtightness of the box body. This is because leakage of the liquid cooling box body may cause damage to key components such as chips, and also may cause serious damage to the liquids inside the box body, thus having severe consequences.

Most of the existing liquid cooling box bodies are additionally provided with reinforced structures on their top covers, which increases weight of the top covers and is disadvantageous to maintenance by operation and maintenance staff when it is unable to achieve expected sealing effects.

In an existing embodiment, to avoid failure of normal use and maintenance of the liquid cooling box body due to excessive weight and poor airtightness of the top cover of the liquid cooling box body, and to prevent from causing damages to interior of the liquid cooling box body, there is an urgent need for a top cover sealing structure for the liquid cooling box body of a data room, which can ensure the airtightness of the liquid cooling box body while meeting the lightweight of the top cover.

The technical solutions in the embodiments of the present disclosure will be clearly and completely described below with reference to the accompanying drawings. Apparently, the embodiments described in the present disclosure are some but not all of the embodiments of the present disclosure. All other embodiments obtained by a person of ordinary skill in the art based on the embodiments of the present disclosure without creative efforts shall fall within the protection scope of the present disclosure.

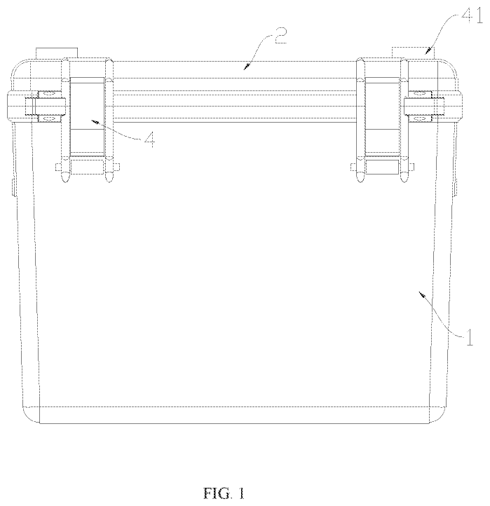

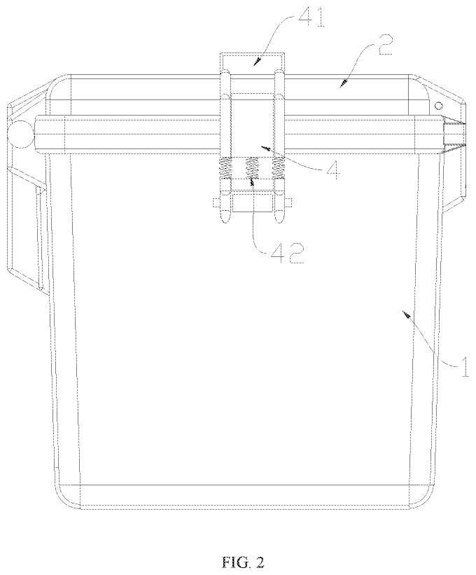

In an implementable embodiment, as shown in FIG. 1 and FIG. 2, a top cover sealing structure for a liquid cooling box body of a data room may at least include a box body 1 and a top cover 2. One side of the top cover 2 is hinged with the box body 1, and the box body 1 is provided with a pressure rod 4, which can match with the top cover 2 and press the top cover 2 towards the box body 1. By reducing the distance between the box body 1 and the top cover 2, the airtightness of the box body 1 is improved.

Specifically, the box body 1 is a hollow structure with an opening facing upwards to ensure that a server can be placed in the box body 1. The box body 1 is filled with non-conducting liquid, which immerses the server and cools the server. A size of the top cover 2 matches the box body 1, and the top cover 2 can rotate above the opening of the box body 1. When the top cover 2 comes into contact with the box body 1, the top cover 2 can cover the opening of the box body 1 to prevent the liquid from flowing out of the box body 1.

In this embodiment, the pressure rod 4 is hinged on a side wall of the box body 1 and can be flipped along a height of the box body 1. A free end of the pressure rod 4 is a bending structure 41, and a length of the pressure rod 4 is equal to or slightly greater than a distance between an upper surface of the top cover 2 and a hinge point of the pressure rod 4. After the pressure rod 4 rotates, a corner of the bending structure 41 can be clamped and fixed by an edge of the top cover 2. In this case, a bottom surface of the bending structure 41 comes into contact with the upper surface of the top cover 2, so the bending structure 41 can convert its own gravity into pressure and evenly apply the pressure to the top cover 2 to provide a downward pressure applied by the top cover 2, thereby reducing the distance between the box body 1 and the top cover 2.

Further, the pressure rod 4 is provided with a spring 42. When the bending structure 41 is positioned away from the top cover 2, the spring 42 is in a natural state. When the bending structure 41 comes into contact with the upper surface of the top cover 2, the spring 42 is in a stretched state. In this way, even if the length of the pressure rod 4 is less than or equal to the distance between the upper surface of the top cover 2 and the hinge point of the pressure rod 4, the bending structure 41 can be stretched above the top cover 2 through the spring 42. Next, elasticity of the spring 42 can allow the bottom surface of the bending structure 41 to come into contact with the upper surface of the top cover 2, and the top cover 2 is pressed towards the box body 1, thereby achieving a tight fit between the box body 1 and the top cover 2.

Further, the free end of the bending structure 41 is provided with a storage plate, which can form a storage area together with the bending structure 41. As a rectangular solid with a hollow structure, the storage area has a storage port at one end, where the storage port is positioned on a side of the storage area away from the pressure rod 4, and a size of the storage area is larger than that of the pressure block, such that the pressure block can be inserted into the storage area from the storage port and is placed in the storage area. The pressure exerted by the bending structure 41 against the top cover 2 is increased by means of the weight of the pressure block. Furthermore, by adopting this installation method, the pressure block can be easily installed and replaced by operation and maintenance staff. For example, when a gap between the box body 1 and the top cover 2 is too large, a size of the gap may be adjusted by increasing the weight of the pressure block. In addition, because the pressure block is arranged on the bending structure 41, it is only required to rotate the pressure rod 4 when opening or closing the top cover 2, which is more convenient compared to directly placing the pressure block on the top cover 2. Furthermore, a direction of arrangement of the storage port allows that the pressure block does not slide out of the storage area during the rotation of the pressure rod 4.

In practical applications, to ensure uniform force distribution on the top cover 2, the pressure rod 4 maybe respectively provided on two sides of the box body 1. Furthermore, users may select appropriate installation positions and quantities of the pressure rods 4 based on actual situations of the liquid cooling box body, such that adjustment of the distance between the top cover 2 and the box body 1 can be achieved, thereby solving the problem of poor airtightness of the existing liquid cooling box body.

More specifically, at least two pressure rods 4 are installed on other three surfaces of the box body 1 except for a surface hinged with the top cover 2. Advantages of adopting the above design mode is that the entire top cover 2 can be stably compressed as a whole by means of a plurality of evenly distributed pressure rods 4.

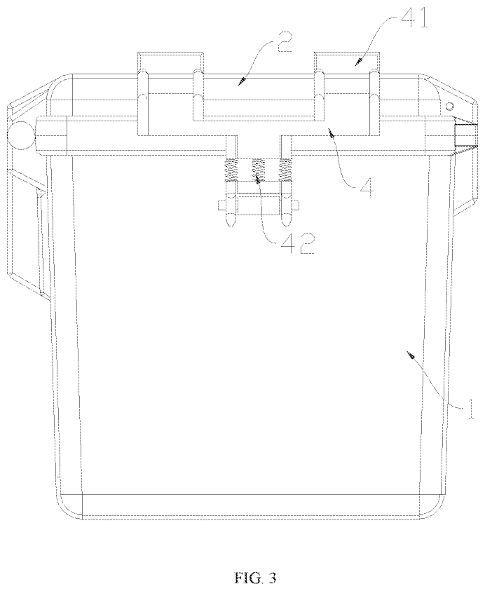

As a preferred embodiment of the above technical solutions, as shown in FIG. 3, the pressure rod 4 positioned on the two sides of the box body 1 includes a mounting part and two clamping parts. The spring 42 is arranged on the mounting part, and the two clamping parts are respectively positioned on two sides of the mounting part and are connected to the mounting part at their bottoms, making the pressure rod 4 in a Y-shaped structure. One end of the mounting part far away from the clamping parts is hinged with the box body 1, and each of the two clamping parts has the bending structure 41. Due to existence of a certain distance between the two mounting parts, two different positions of the top cover 2 can be compressed simultaneously, thereby increasing a compression range and saving installation space of the pressure rod 4.

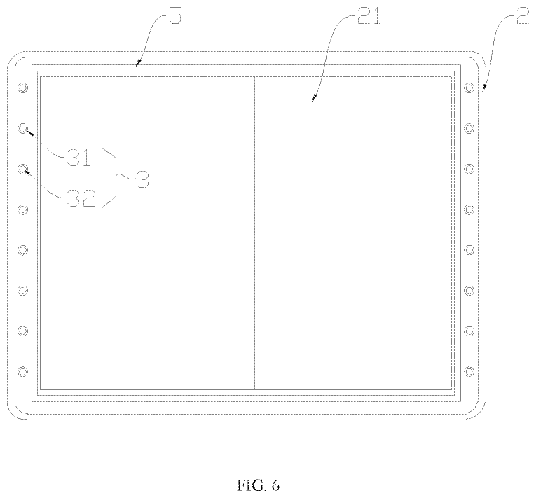

In an implementable embodiment, as shown in FIG. 6, a visible window 21 is provided on the top cover 2, which facilitates the operation and maintenance staff to observe internal conditions of the liquid cooling box body.

Specifically, due to lower temperature of a coolant liquid stored in the box body 1, materials selected for the visible window 21 need to be able to withstand a certain pressure difference caused by a temperature difference between inside and outside of the box body 1, and a portion of heat from inside the box body 1 maybe absorbed and dissipated into external air.

Further, a surface of the visible window 21 is coated with a hydrophobic coating. The hydrophobic coating comprised of hydrophobic coatings has characteristics such as waterproofing and antifogging, which can ensure that there is no dripping phenomenon inside the visible window 21 after the coolant liquid vaporizes, avoiding a situation where interior of the liquid cooling box body cannot be observed during use.

Further, a sealing crimping adhesive is provided at a connection between the visible window 21 and the top cover 2 to enhance sealing performance between the visible window 21 and the top cover 2.

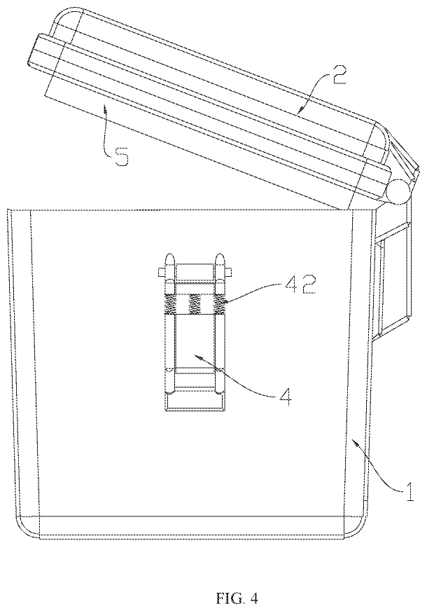

In an implementable embodiment, as shown in FIG. 4 and FIG. 6, the bottom surface of the top cover 2 is provided with a sealing block 5 matching a shape of the opening of the box body 1. Specifically, when the opening is circular, the sealing block 5 is shaped like a circular ring; and when the opening is square, the sealing block 5 is shaped like a square ring. The sealing block 5 is arranged around the visible window 21 and is smaller in size than the opening. When the top cover 2 is closed, the sealing block 5 is positioned inside the opening, and an outer wall of the sealing block 5 comes into contact with an inner wall of the opening. By providing the sealing block 5, interior and exterior of the box body 1 are sealed, thereby reducing possibility of outflow of liquid.

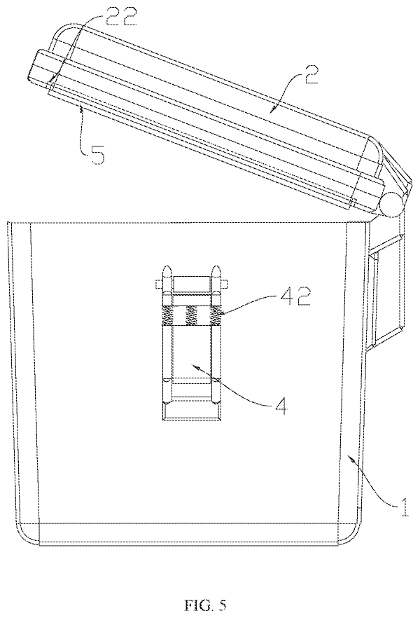

Different from the above embodiments, in another embodiment, as shown in FIG. 5, the bottom surface of the top cover 2 is provided with a sealing groove 22 matching a shape of the sealing block 5, where a size of the sealing groove 22 is larger than the opening. The sealing block 5 is arranged inside the sealing groove 22 and is smaller than the sealing groove 22 in size. A length of the sealing block 5 is greater than a depth of the sealing groove 22, and the free end extends towards the direction of the box body 1. The sealing block 5 in this embodiment adopts a material that can generate elastic deformation. When the top cover 2 is closed, a bottom surface of the sealing block 5 comes into contact with the upper surface of the box body 1, and the box body 1 squeezes the sealing block 5. In this case, two sides of the sealing block 5 move towards the sealing groove 22, such that the sealing block 5 fills the sealing groove 22, and reduces the distance between the box body 1 and the top cover 2 using its own elasticity, thereby improving the airtightness of the liquid cooling box body.

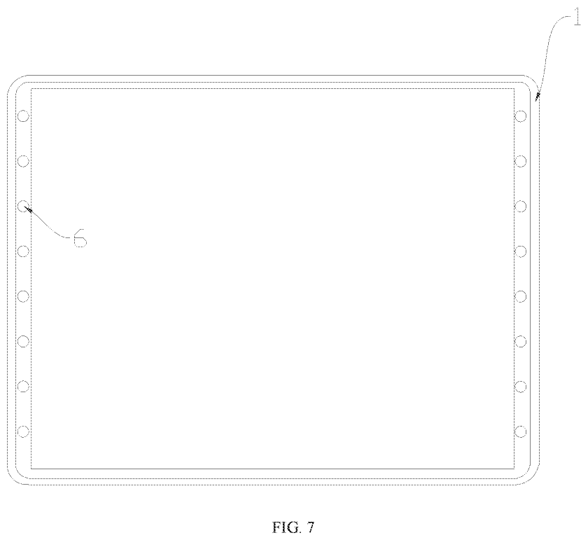

In an implementable embodiment, as shown in FIG. 7, the bottom surface of the top cover 2 is provided with a sealing structure 3, which includes a plurality of sealing installation plates 31 and sealing bodies 32, where the plurality of sealing installation plates 31 are arranged along an edge of the top cover 2, and each of the plurality of sealing installation plates 31 is provided with at least one of the sealing bodies 32. The box body 1 is provided, along an edge of the opening, with sealing holes 6 equal to the sealing bodies 32 in number and corresponding to the sealing bodies 32 in position from up to down. When the top cover 2 is closed by means of rotation, the sealing bodies 32 can be inserted into the corresponding sealing holes 6. In this embodiment, the top cover 2 can be guided when it is closed, and the position of the top cover 2 can be fixed after it is closed, to prevent the top cover 2 from being pushed during the use of the pressure rod 4, thereby preventing the top cover 2 from not completely covering the opening.

The sealing body 32 maybe made of metal materials or elastic materials, but the materials of the sealing body 32 in the present disclosure are not limited thereto.

Specifically, when the sealing body 32 is made of the metal materials, to avoid wear and tear caused by repeated collision between the sealing body 32 and the sealing hole 6, buffer rubber is provided at the bottom of the sealing body 32 and inside the sealing hole 6 to reduce impact forces generated by the collision between the sealing body 32 and the sealing hole 6. When the sealing body 32 is made of the elastic materials, during use, after the sealing body 32 comes into contact with the sealing hole 6, the bottom of the sealing body 32 will be compressed, and the sealing body 32 will expand inside the sealing hole 6 to effectively seal the connection between the box body 1 and the top cover 2, thereby effectively improving the airtightness of the liquid cooling box body.

The embodiments set forth above are only illustrated as preferred embodiments of the present disclosure, and are not intended to limit the present disclosure. All modifications, equivalent substitutions and improvements made within the spirit and principles of the present disclosure shall fall within the protection scope of the present disclosure.

What is claimed is:

1. A top cover sealing structure for a liquid cooling box body of a data room, at least comprising a box body (1) and a top cover (2), wherein one side of the top cover (2) is hinged with the box body (1) and can cover an opening of the box body (1);
the box body (1) is provided with a pressure rod (4), and the pressure rod can press the top cover (2) towards the box body (1); and
the pressure rod (4) is provided with a spring (42), and a free end of the pressure rod (4) is detachably provided with a pressure block.

2. The top cover sealing structure for the liquid cooling box body of the data room according to claim 1, wherein one end of the pressure rod (4) is hinged with a side wall of the box body (1), other end of the pressure rod (4) is forked to form two bending structures (41), and the pressure block is sleeved at an end of the bending structure (41); and
a length of the pressure rod (4) is less than or equal to a distance between an upper surface of the top cover (2) and a hinge point of the pressure rod (4), when the pressure rod (4) rotates, the spring (42) can cause a corner of the bending structure (41) to be clamped by an edge of the top cover (2), the pressure block is positioned inside the bending structure (41), and a downward pressure applied to the top cover (2) can be provided.

3. The top cover sealing structure for the liquid cooling box body of the data room according to claim 1, wherein a bottom surface of the top cover (2) is provided with a sealing block (5), the sealing block (5) matches a shape of an opening of the box body (1), and when the top cover (2) is closed, the sealing block (5) can come into contact with the opening.

4. The top cover sealing structure for the liquid cooling box body of the data room according to claim 3, wherein a size of the sealing block (5) is smaller than the opening, and when the top cover (2) is closed, the sealing block (5) is positioned inside the opening, and an outer wall of the sealing block (5) comes into contact with an inner wall of the opening.

5. The top cover sealing structure for the liquid cooling box body of the data room according to claim 3, wherein the bottom surface of the top cover (2) is provided with a sealing groove (22) matching a shape of the sealing block (5), and the sealing block (5) is arranged inside the sealing groove (22), a size of the sealing block (5) is smaller than a size of the sealing groove (22), and an end of the sealing block (5) extends towards a direction of the box body (1); and
the sealing block (5) is made of a material that can generate elastic deformation, and when the top cover (2) is closed, a bottom surface of the sealing block (5) comes into contact with an upper surface of the box body (1), and the box body (1) squeezes the sealing block (5) such that the sealing block (5) fills the sealing groove (22).

6. The top cover sealing structure for the liquid cooling box body of the data room according to claim 1, wherein a bottom surface of the top cover (2) is provided with a sealing structure (3) comprising a plurality of sealing installation plates (31) and sealing bodies (32), the plurality of sealing installation plates (31) are arranged along an edge of the top cover (2), and each of the plurality of sealing installation plates (31) is provided with at least one of the sealing bodies (32); and
the box body (1) is provided, along an edge of the opening, with sealing holes (6) equal to the sealing bodies (32) in number and corresponding to the sealing bodies (32) in position from up to down, and when the top cover (2) is closed, the sealing bodies (32) can be inserted into the corresponding sealing holes (6).

7. The top cover sealing structure for the liquid cooling box body of the data room according to claim 6, wherein the sealing bodies (32) are made of metal materials, and buffer rubber is provided at bottoms of the sealing bodies (32) and inside the sealing holes (6).

8. The top cover sealing structure for the liquid cooling box body of the data room according to claim 6, wherein the sealing bodies (32) are made of elastic materials, and when the sealing bodies (32) come into contact with the sealing holes (6), the sealing holes (6) squeeze the sealing bodies (32), such that the sealing bodies (32) fill the sealing holes (6).

9. The top cover sealing structure for the liquid cooling box body of the data room according to claim 1, wherein a visible window (21) is arranged on the top cover (2).
